(19) United States
(12) Patent Application Publication
(10) Pub. No.: US 2023/0335625 A1
(43) Pub. Date: Oct. 19, 2023

(54) POWER SEMICONDUCTOR DEVICE

(71) Applicants: DYNEX SEMICONDUCTOR LIMITED, Lincoln (GB); ZHUZHOU CRRC TIMES ELECTRIC CO. LTD, Zhuzhou (CN)

(72) Inventors: Chunlin Zhu, Lincoln (GB); Guoyou Liu, Zhuzhou (CN)

(21) Appl. No.: 18/009,677

(22) PCT Filed: Mar. 31, 2021
(86) PCT No.: PCT/CN2021/084458

§ 371 Date: Dec. 9, 2022

(51) Int. Cl. H01L 29/739; H01L 29/78; H01L 29/06; H01L 27/06; H01L 29/66

(52) U.S. Cl. CPC H01L 29/7397; H01L 29/7813; H01L 29/0696; H01L 27/0623; H01L 29/66348; H01L 29/66734; H01L 29/7827

(57) ABSTRACT

There is provided a power semiconductor device (1), comprising: a semiconductor substrate (2) comprising: a base layer (5) selectively provided at a first side of the semiconductor substrate, and wherein the base layer has a first conductivity type; a collector layer (3) provided at a second side of the semiconductor substrate, wherein the second side is opposite to the first side, and wherein the collector layer has the first conductivity type; and a drift layer (4) having a second conductivity type opposite to the first conductivity type, wherein the drift layer (4) is arranged between the collector layer (3) and the base layer (5); an active cell (15) provided in the semiconductor substrate (2), wherein the active cell (15) comprises an emitter region (7) which has the second conductivity type and an active base region (5-i) which is a part of the base layer (5); and an insulation trench (17) provided in the semiconductor substrate (2) and neighbouring the active cell (15), wherein: the insulation trench (17) extends from a surface (16) of the semiconductor substrate (2) at the first side into the drift layer (4) along a first direction; the insulation trench (17) comprises a gate electrode (9) and a dielectric material (11, 10) disposed therein; and the gate electrode (9) is configured to control an on/off status of a current channel within the active cell (15); wherein the active cell (15) has a first length L1 along a second direction X perpendicular to the first direction Y, and the insulation trench (17) has a second length L2 along the second direction X, and the first and second lengths L1 and L2 satisfy the relationship of 0.5≤L2/L1≤2.

### TECHNICAL FIELD

The present disclosure relates to a power semiconductor device. More particularly, but not exclusively, the present disclosure relates to a trench-gate power semiconductor device with an insulation trench.

### BACKGROUND

Power semiconductor devices (such as, insulated-gate bipolar transistors (IGBTs)) have been widely used as power switches in a variety of power applications. Important operating parameters of IGBTs typically include the on-state voltage drop between the collector and the emitter (V_{CE,sat}), the switching loss (E_{SW}), and the safe operating area (SOA). V_{CE,sat} and E_{SW} indicate the efficiency of an IGBT while SOA indicates the reliability of an IGBT. Generally speaking, there are two common types of IGBT structures. One type is called a planar-gate IGBT in which a gate electrode is provided on a surface of a wafer. The other type is called a trench-gate IGBT in which a trench structure is formed in a wafer and a gate electrode is buried in the trench structure. The trench-gate IGBT has a MOS channel which is vertical to the wafer surface, and the vertical MOS channel effectively eliminates a JFET effect in the planar gate structure. Concurrently, as the MOS channel density is not limited by the chip surface area, the channel density can be improved greatly. In this way, as compared to the planar-gate IGBT, the trench-gate IGBT can provide an increased channel density and accordingly a reduced on-state voltage drop V_{CE,sat}. However, the trench-gate IGBT has a worse short-circuit current capability or a poorer short-circuit SOA (SCSOA) due to its high saturation collector current density. Therefore, in the latest trench gate technology, dummy regions have been adopted to optimize the trade-off performance between V_{CE,sat} and SCSOA without sacrificing the reverse blocking voltage.

The dummy regions (which include dummy trenches as well as dummy wells between the dummy trenches) introduce additional parasitic capacitance and more space to store free electron-hole carriers which need to be removed or flood in when the device is turned off or turned on. It has been reported that the dummy trenches could be electrically connected to the active gate electrodes of the trench-gate IGBT, but this type of connections would result in large switching loss due to increased gate-collector capacitance (C_{GC}). It is also known that the dummy trenches may be electrically connected to the emitter electrode of the IGBT, but this type of connections would increase the turn-on switching speed (represented by the rate of change of the collector current, di/dt) and result in uncontrollable di/dt through changing a gate resistor R_{g,on}.

Therefore, it is often required to trade off one operating parameter of an IGBT for the improvement of another operating parameter of the IGBT. Similar problems exist for other types of power semiconductor devices.

It is generally desirable to provide a power semiconductor device which has an improved device efficiency as well as an improved reliability.

### SUMMARY

It is an object of the present disclosure, among others, to provide an improved power semiconductor device which solves the problems associated with known structures, whether identified herein or otherwise.

According to a first aspect of the present disclosure, there is provided a power semiconductor device, comprising:
a semiconductor substrate comprising:
   a base layer selectively provided at a first side of the semiconductor substrate, and wherein the base layer has a first conductivity type;
   a collector layer provided at a second side of the semiconductor substrate, wherein the second side is opposite to the first side, and wherein the collector layer has the first conductivity type; and
   a drift layer having a second conductivity type opposite to the first conductivity type, wherein the drift layer is arranged between the collector layer and the base layer;
an active cell provided in the semiconductor substrate, wherein the active cell comprises an emitter region which has the second conductivity type and an active base region which is a part of the base layer; and
an insulation trench provided in the semiconductor substrate and neighbouring the active cell, wherein: the insulation trench extends from a surface of the semiconductor substrate at the first side into the drift layer along a first direction; the insulation trench comprises a gate electrode and a dielectric material disposed therein; and the gate electrode is configured to control an on/off status of a current channel within the active cell;
wherein the active cell has a first length L1 along a second direction perpendicular to the first direction, and the insulation trench has a second length L2 along the second direction, and the first and second lengths L1 and L2 satisfy the relationship of 0.5≤L2/L1≤2.

As compared to prior designs of power semiconductor devices (e.g., IGBTs) which provide a dummy semiconductor region to neighbour an active cell, using the insulation trench of the first aspect to replace at least a part of the dummy semiconductor region is advantageous for improving the SOA and the switching controllability, and reducing the switching loss and the EMI noise of the power semiconductor device, while providing a similar level of current density. The length L1 of the active cell and the length L2 of the insulation trench follows the design rule of 0.5≤L2/L1≤2, which is useful for keeping uniform electric field distribution on the chip front side (thereby improving the reliability of the device) and for maintaining process uniformity and controllability. L2/L1 refers to a ratio of the second length L2 and the first length L1.

It would be appreciated that the active cell refers to a minimum repeating unit that is able to conduct current in a whole power semiconductor device, and that the active cell is configured to provide at least one current channel during an on-state of the power semiconductor device.

Since the gate electrode is able to control an on/off status of a current channel within the active cell, the gate electrode is therefore an active gate electrode. It would be appreciated that the gate electrode is arranged adjacent to the emitter region, so as to control an on/off status of a current channel provided by the active cell.

The gate electrode may extend from the surface of the semiconductor substrate at the first side into the semiconductor substrate along the first direction.

The current channel provided by the active cell may be generally along the first direction.

A part of the dielectric material may act as a gate insulator between the emitter region and the gate electrode.

The emitter region may be selectively provided at the first side of the semiconductor substrate. Preferably, the first and second lengths L1 and L2 may further satisfy the relationship of L2/L1≤1.7. More preferably, the first and second lengths L1 and L2 may further satisfy the relationship of L2/L1≤1.5. By making L2/L1 not greater than 2, preferably not greater than 1.7, and most preferably not greater than 1.5, the electric field under the insulation trench may be prevented from reaching an excessive level when the device is reversely biased, thereby protecting the device from breaking down.

Preferably, the first and second lengths L1 and L2 may further satisfy the relationship of L2/L1≥1. By making L2/L1 not lower than 0.5, more preferably not lower than 1, the risk of the device suffering from a high short circuit current is reduced, thereby allowing the device to have an acceptance SCSOA performance.

The active cell may further comprise a first implant zone provided between the active base region and the drift layer. The first implant zone may be of the second conductivity type and has a higher doping concentration than the drift layer.

Advantageously, the first implant zone improves the conductivity modulation in the power semiconductor device by enhancing the carrier profile in the drift layer during the on state, thereby reducing V_{CE,sat} of the power semiconductor device.

The power semiconductor device may comprise a further insulation trench neighbouring the active cell. The further insulation trench may extend from the surface of the semiconductor substrate into the drift layer along the first direction and may comprise a gate electrode and a dielectric material disposed therein. The gate electrode of the further insulation trench may be configured to control an on/off status of a further current channel within the active cell.

The current channel and the further current channel may be arranged at opposite sides of the active cell.

The gate electrode may be a first gate electrode, and the insulation trench may comprise a second gate electrode. The first and second gate electrodes may be arranged at opposite sides of the insulation trench.

The second gate electrode may be an active gate electrode or a dummy gate electrode.

The active cell may further comprise a dummy gate trench, the dummy gate trench comprising a dummy gate insulator and a dummy gate electrode disposed therein.

The insulation trench and the dummy gate trench may have substantially the same depth along the first direction.

The active cell may comprise a plurality of the dummy gate trenches.

The current channel and the further current channel of the active cell may be provided at opposite sides of the dummy gate trench or the plurality of the dummy gate trenches.

The dummy gate trench may be arranged in the middle of the active cell along the second direction.

The power semiconductor device may further comprise an emitter electrode. The emitter electrode may comprise an emitter contact trench extending along the first direction into the base layer. The emitter contact trench may be electrically connected to the emitter region and the dummy gate electrode.

The emitter contact trench advantageously simplifies the electrical connection between the dummy gate electrode and the emitter electrode, and allows the minimum distance between the gate electrode and the dummy gate trench to be reduced, thereby improving the current density and the on state voltage drop of the power semiconductor device. The emitter contact trench is further useful for improving the holes collection capability of the emitter electrode, thereby improving the SOA performance of the device.

In the event that the active cell comprises a plurality of the dummy gate trenches, the emitter contact trench may be electrically connected to the dummy gate electrode of each of the dummy gate trenches.

The gate electrode of the insulation trench may have a greater length than the dummy gate electrode along the first direction. In other words, the dummy gate trench may be etched in order to form the emitter contact trench.

The emitter contact trench may have a greater length than the dummy gate trench along the second direction.

In the event that the active cell comprises a plurality of the dummy gate trenches, the emitter contact trench may have a greater length than the plurality of the dummy gate trenches along the second direction

The emitter contact trench may be arranged in the middle of the active cell along the second direction.

The power semiconductor device may further comprise a second implant zone between the insulation trench and the drift layer, the second implant zone having the first conductivity type.

In particular, the second implant region may be between the gate electrode of the insulation trench and the drift layer.

Advantageously, the second implant zone shields the gate electrode and its associated gate insulator (provided by the dielectric layer) from the bombing holes injected by the collector layer during an on state of the power semiconductor device, and accordingly, protects the gate electrode and the gate insulator from trapping holes bombing from the collector layer. As a result, the second implant zone improves the reliability of the power semiconductor device. Further, the second implant zone provides better blocking capability for the power semiconductor device.

The second implant zone may be electrically connected to the emitter electrode or floating.

The second implant zone may also be provided within the active cell between the dummy gate trench and the drift layer.

Advantageously, the second implant zone between the dummy gate trench and the drift layer provides better blocking capability for the power semiconductor device, and may be electrically connected to the emitter electrode or floating.

The second direction may be parallel to the surface of the semiconductor substrate.

The power semiconductor device may further comprise a dummy cell. The dummy cell may comprise a dummy base region which is a part of the base layer.

It would be appreciated that the dummy cell does not provide any current channel during an on-state of the power semiconductor device.

The dummy cell may not comprise any emitter region formed within the dummy base region.

The dummy cell may further comprise a dummy gate trench which comprises a dummy gate insulator and a dummy gate electrode disposed therein.

The dummy cell may comprise a plurality of the dummy gate trenches.

The active cell and the dummy cell may comprise the same number of dummy gate trenches.

A length of the dummy cell along the second direction may be equal to the first length L1.

The first implant zone may also be provided within the dummy cell between the dummy base region and the drift layer.

The second implant zone may also be provided within the dummy cell between the dummy gate trench and the drift layer.

Advantageously, the second implant zone between the dummy gate trench and the drift layer provides better blocking capability for the power semiconductor device, and may be electrically connected to the emitter electrode.

The power semiconductor device may comprise a plurality of the active cells and a plurality of the insulation trenches, and each active cell is provided immediately between two of the insulation trenches along the second direction.

The expression “immediately between” means that there is no other structure between two of the insulation trenches.

The power semiconductor device may further comprise a plurality of the dummy cells, and wherein at least one of the dummy cells and at least two of the insulation trenches are provided between neighbouring ones of the active cells along the second direction.

The insulation trenches may be provided between a dummy cell and an active cell, or between two dummy cells, along the second direction.

The power semiconductor device may further comprise a buffer layer having the second conductivity type, wherein the buffer layer is provided between the drift layer and the collector layer, and has a higher doping concentration than the drift layer.

The buffer layer is useful for reducing the on-state voltage drop V_{CE,sat} of the power semiconductor device.

The power semiconductor device may comprise an insulated-gate bipolar transistor (IGBT).

According to a second aspect of the present disclosure, there is provided a method of manufacturing a power semiconductor device, the method comprising:
providing a semiconductor substrate comprising:
   a base layer provided at a first side of the semiconductor substrate, wherein the base layer has a first conductivity type; and
   a drift layer having a second conductivity type opposite to the first conductivity type;
selectively etching the base layer and the drift layer to form an insulation trench within the semiconductor substrate;
forming a gate electrode within the insulation trench and filling the insulation trench with a dielectric material;
selectively forming an emitter region having the second conductivity type within the base layer at the first side of the semiconductor substrate, wherein the emitter region and a part of the base layer in which the emitter region is arranged provide an active cell, and wherein the insulation trench neighbours the active cell, and the gate electrode is configured to control an on/off status of a current channel within the active cell; and
forming a collector layer at a second side of the semiconductor substrate, the collector layer having the first conductivity type, wherein the second side is opposite to the first side, and the drift layer is arranged between the collector layer and the base layer;
wherein:
the insulation trench is configured to extend from a surface of the semiconductor substrate at the first side into the drift layer along a first direction;
the active cell has a first length L1 along a second direction perpendicular to the first direction, and the insulation trench has a second length L2 along the second direction; and
the first and second lengths L1 and L2 satisfy the relationship of 0.5≤L2/L1≤2.

Where appropriate any of the optional features described above in relation to the first aspect of the present disclosure may be applied to the second aspect of the disclosure.

It would be appreciated that the various ranges of L2/L1 described above allow for a degree of variability, for example, ±10%, in the stated values of the end points of the ranges. For instance, a stated limit of 2 may be any number between 2*(1−10%), and 2*(1+10%). Further, values expressed in a range format should be interpreted in a flexible manner to include not only the numerical values explicitly recited as the end points of the range, but also to include all the individual numerical values or sub-ranges encompassed within that range as if each numerical value and sub-range is explicitly recited.

### BRIEF DESCRIPTION OF THE DRAWINGS

In order that the disclosure may be more fully understood, a number of embodiments of the present disclosure will now be described, by way of example, with reference to the accompanying drawings, in which:

FIG. 1 is a schematic representation of a cross sectional view of a power semiconductor device according to a first embodiment of the present disclosure;

FIG. 2 is a schematic representation of a cross sectional view of a power semiconductor device according to a second embodiment of the present disclosure;

FIG. 3 is a schematic representation of a cross sectional view of a power semiconductor device according to a third embodiment of the present disclosure;

FIG. 4 is a schematic representation of a cross sectional view of a power semiconductor device according to a fourth embodiment of the present disclosure;

FIG. 5 is a schematic representation of a cross sectional view of a power semiconductor device according to a fifth embodiment of the present disclosure;

FIGS. 6-1 to 6-8 illustrate a method for manufacturing a power semiconductor device according to the third embodiment.

In the figures, like parts are denoted by like reference numerals.

It will be appreciated that the drawings are for illustration purposes only and are not drawn to scale.

### DETAILED DESCRIPTION OF THE PREFERRED EMBODIMENTS

Hereafter, referring to the attached drawings, a detailed description will be given of preferred embodiments of a power semiconductor device according to the disclosure. A layer or region being prefixed by N or P in the description and attached drawings means that electrons or holes respectively are majority carriers. Also, ‘+’ or ‘−’ added to N or P indicates a higher impurity concentration or lower impurity concentration respectively than in a layer or region to which ‘+’ or ‘−’ is not added. Doping regions of the same relative doping concentration do not necessarily have the same absolute doping concentration. For example, two different ‘N’ doping regions may have the same or different absolute doping concentrations. In the following descriptions and attached drawings, the same reference signs are given to the same configurations, and redundant descriptions are omitted.

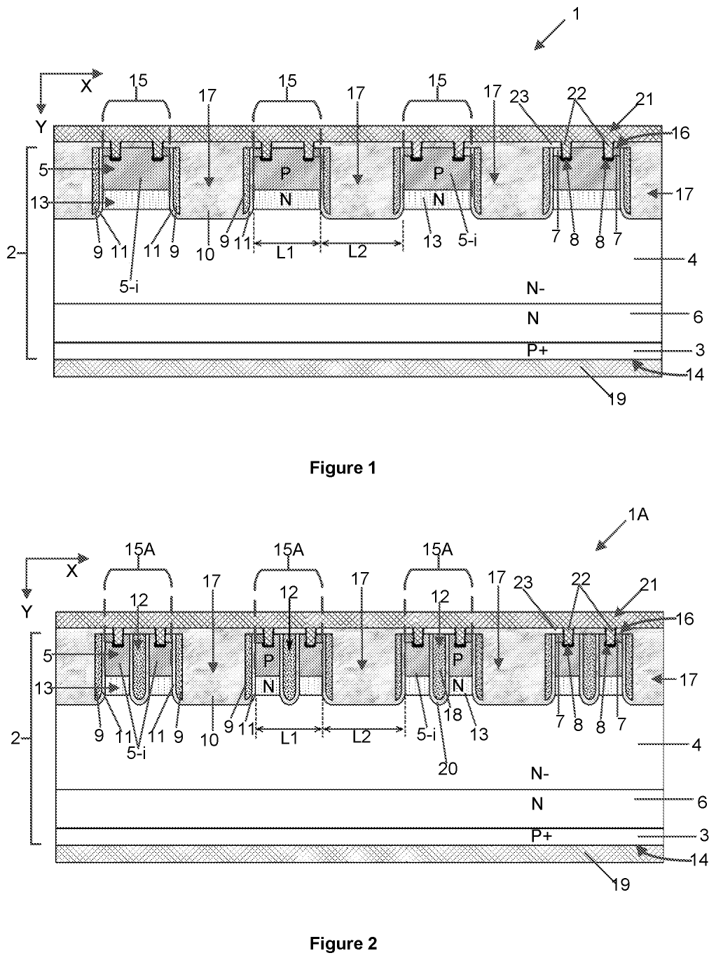

FIG. 1 schematically illustrates a cross-sectional view of a power semiconductor device 1 according to a first embodiment of the present disclosure. In the example provided by FIG. 1, the power semiconductor device is embodied as a trench-gate IGBT. The IGBT 1 is formed on a semiconductor substrate 2. The semiconductor substrate 2 comprises a P type base layer 5 provided at a first side (e.g., the top side) of the substrate, a P+ type collector layer 3 provided at a second opposite side (e.g., the bottom side) of the substrate, a N− type drift layer 4 between the collector layer 3 and the base layer 5, and a N type buffer layer 6 between the P+ type collector layer 3 and the N− type drift layer 4. The semiconductor substrate 2 has a first surface 16 (e.g., the top surface) at the first side and a second surface 14 (e.g., the bottom surface) at the second side. The second surface 14 is a surface of the P+ type collector layer 3. The first surface 16 is a surface of the P type base layer 5.

A plurality of active cells 15 and a plurality of insulation trenches 17 are formed within the semiconductor substrate 2. As shown in FIG. 1, the active cells 15 and the insulation trenches 17 are arranged in an alternating manner along an X axis. In other words, an insulation trench 17 is provided immediately between two adjacent active cells 15. There is no other structure between neighbouring ones of the active cells. The X axis is generally parallel to the first surface 16 or the second surface 14 of the substrate 2. Each active cell 15 refers to a minimum repeating unit that is able to conduct current in the IGBT 1. While FIG. 1 shows that the IGBT 1 has four active cells 15, it would be understood that this is just for conceptual illustration, and that in reality, an IGBT may typically have at least hundreds to thousands of active cells. The active cells 15 are designed to have almost identical dimensions and configurations. With the expression “active cell”, it is meant that the cell would provide at least one current channel during an on-state of the IGBT 1.

As illustrated in FIG. 1, each insulation trench 17 extends from the first surface 16 of the substrate 2 into the N− type drift layer 4 along a Y axis. The Y axis is generally perpendicular to the first surface 16 or the second surface 14. The Y axis may also be referred to as the “first direction” or the depth direction of the substrate 2, and the X axis may also be referred to as the “second direction” or the lateral direction of the substrate 2. Each insulation trench comprises two gate electrodes 9 disposed at opposite sides of the respective insulation trench. The two gate electrodes 9 are disposed adjacent to the two active cells neighbouring the insulation trench, respectively. Each of the gate electrodes 9 also extends along the Y axis. As shown in FIG. 1, the gate electrodes 9 of the insulation trenches 17 are aligned in the X axis. The gate electrodes 9 may be formed using any material typically utilized in the art, such as, doped polysilicon.

Each insulation trench further comprises at least one dielectric material disposed therein. The dielectric material provides two gate insulators 11 for the two gate electrodes 9, respectively. The gate insulators 11 are disposed between the gate electrodes 9 and the active cells neighbouring the insulation trench. The dielectric material also provides an isolation structure 10 between the two gate electrodes 9. The isolation structure 10 is distinguished from the gate insulators 11 by being formed as a thicker trench insulation than the gate insulators 11. The gate insulators 11 and the isolation structure 10 may be made of the same dielectric material or different types of dielectric materials. The gate insulators 11 may be formed using any material and any technique typically employed in the art. For example, the gate insulator 11 may be a gate oxide, such as silicon dioxide, and may be deposited or thermally grown to produce gate insulators 11. The thick isolation structure 10 may be deposited.

As shown in FIG. 1, the P type base layer 5 is divided by the insulation trenches 17 into a plurality of isolated P type base regions 5-i. Each active cell 15 comprises one of the P type base regions 5-i. The P type active base regions 5-i may also be referred to as active P wells. As described below in more detail, at least one current conducting channel is formed within the P type base regions 5-i during an on state of the IGBT 1. Therefore, the P type base regions 5-i of the active cells 15 may also be referred to as P type active base regions. As further shown in FIG. 1, there is a first implant zone 13 between each active base region 5-i and the N− drift layer 4. The first implant zone 13 is N type. As its name suggests, the first implant zone 13 was formed by implantation. Therefore, all of the first implant zones 13 may be formed in the substrate 2 simultaneously. Each active cell 15 further comprises two N+ type emitter regions 7. The emitter regions 7 are adjacent to the first surface 16 of the substrate 2 along the Y axis, and adjacent to the gate electrodes 9 of neighbouring insulation trenches 17 along the X axis.

The IGBT 1 further comprises a collector electrode 19 which is electrically connected to the P+ type collector layer 3, an emitter electrode 21 which is electrically connected to each emitter region 7. The emitter electrode 21 may include a barrier layer made of titanium nitride, tantalum nitride, titanium or tantalum by way of example. A main layer of the emitter electrode 21 may be made of, for example, tungsten or tungsten-based metals, aluminium, copper, or alloys of aluminium and copper. The collector electrode 19 may comprise aluminium, copper, alloys of aluminium or copper, or multiple layers of metals, e.g. Al/Ti/Ni/Ag or Al/Ni/Ag, etc. Although the electrical connections among the gate electrodes 9 of the insulation trenches 17 are not explicitly shown in the cross-sectional perspective provided by FIG. 1, the gate electrodes 9 can be shorted together in the third dimension relative to the cross-sectional plane of FIG. 1.

An interlay dielectric 23 covers an upper portion of the active cells 15. Therefore, the interlay dielectric 23 electrically isolates the active gate electrodes 10 from the emitter electrode 21. The emitter electrode 21 includes emitter contact vias 22 which extend through the interlay dielectric 23 to form an electrical connection with the emitter regions 7 and the P type active base regions 5-i. A heavily doped P+ type region 8 is further provided at the interface between each emitter contact via 22 and the corresponding P type active base region 5-i, so as to reduce the contact resistance between the via 22 and the active base region 5-i. The reduced contact resistance is useful in that it allows excess holes injected from the P+ type collector layer 3 into the N− drift layer 4 during an on-state of the IGBT 1 to easily flow towards the emitter electrode 21.

In order to switch the IGBT 1 from an off state to an on state, a positive gate-emitter voltage, V_{GE}, is applied between the gate electrodes 9 and the emitter electrode 21. When V_{GE} is greater than a gate-emitter threshold voltage, parts of the P type active base regions 5-i opposing the gate electrodes 9 across the gate insulators 11 invert to N type, whereby channel regions are formed. Therefore, electrons emitted from the emitter regions 7 are able to flow through the N type channel regions and the N type first implant regions 13 to the N− drift layer 4 and the N type buffer layer 6, before they are collected by the P+ type collector layer 3. In the example of FIG. 1, each active cell 15 is able to provide two current channels (or conducting paths) at opposite sides of the respective active cell during an on state of the IGBT 1. Further, both of the gate electrodes 9 contained within an insulation trench 17 are control electrodes, which control the on/off status of the current channels of neighbouring active cells 15. In this sense, both of the gate electrodes 9 of each insulation trench 17 are active gate electrodes.

In the IGBT 1, any of the gate electrodes 9 and its associated gate insulator 11 may be considered as a trench gate. A semiconductor region between two adjacent active trench gates is commonly referred to as a mesa region or a mesa section. In the example provided by FIG. 1, each mesa region comprises an active base region 5-i and a first implant zone 13. Generally speaking, the centre-to-centre distance (i.e., pitch) between neighbouring mesa regions determines the channel density and accordingly the on-state resistance of an IGBT.

As shown in FIG. 1, each active cell has a first length L1 along the X axis, and each insulation trench has a second length L2 along the X axis. The first length L1 may also be referred to as the length of the mesa region. The lengths L1 and L2 satisfy the design rule of 0.5≤L2/L1≤2. More preferably, the lengths L1 and L2 satisfy the design rule of L2/L1≤1.7 or most preferably L2/L1≤1.5, and/or L2/L1≥1.

The particular design rules between L1 and L2 are advantageous for keeping uniform electric field distribution on the chip front side, and accordingly improve the reliability of the IGBT 1. The chip front side refers to the top surface of a wafer on which the IGBT 1 is manufactured. If L2 is too long with respect to L1, the bottom of the insulation trenches 17 could suffer from higher electric field when the IGBT 1 is reversed biased (i.e., when V_{GE}=0 and V_{CE} is of a positive potential) thereby lowering the breakdown voltage of the IGBT 1. On the other hand, if L2 is too short with respect to L1, the IGBT 1 may suffer from higher short circuit current, thereby worsening the SCSOA performance of the IGBT 1.

Further, the particular design rules are useful for maintaining process uniformity and controllability. As described below in more detail, a semiconductor substrate may be etched to provide the insulation trenches 17 simultaneously in a single dry etching step. With L2 being no longer than two times of L1, the lengths L1 and L2 are of comparable scales. As such, the etching depths of the semiconductor substrate may be maintained uniformly across the chip area. This means that the insulation trenches 17 would have substantially the same depth along the Y axis. In addition, if L2 is too long with respect to L1, it may be difficult to control the process of filling the insulation trenches 17 with the dielectric material.

Further, as described in more detail below, the insulation trenches 17 were formed by selectively etching the P type base layer 5 and the N− drift layer 4. The sidewalls of the insulation trenches 17 are parallel to the vertical Y axis as shown in FIG. 1. This may be achieved by anisotropic dry etching. It would be appreciated that the sidewalls of the insulation trenches 17 may form a small angle (e.g., less than 5°) with respect to the Y axis. In that case, the first length L1 may be an average length of an active cell 15, taking into account the length variations along the Y axis. Similarly, the second length L2 may be an average length of a single insulation trench 17, taking into account the length variations along the Y axis.

By adjusting the second length L2 of the insulation trenches 17, it is possible to adjust the current density of the IGBT 1, so as to meet a predefined performance requirement. For example, an IGBT may be required to deliver 200A current within a chip area of 1 cm*1 cm. The required current density may be achieved by adjusting the ratio between the second length L2 and the first length L1.

In prior designs of IGBT, dummy semiconductor regions (also referred to as dummy regions) are commonly provided between adjacent active cells. The known dummy regions typically include a P type dummy base region (which is similar to a part of the P type base layer 5 of the IGBT 1, and may also be referred to as a dummy P well). The dummy base region is usually kept floating, meaning that it is not electronically connected to any electrode and thus has a floating potential. An example of the dummy region is for example shown as the P region 13 in FIG. 9 of U.S. Pat. No. 9,478,614B2. Alternatively, the dummy base region may be grounded or partially grounded. The known dummy regions may also include one or more dummy gate trenches within the dummy base region. An example of the dummy gate trench is shown as the trench 65 in FIG. 9 of U.S. Pat. No. 9,478,614B2.

As compared to the known dummy regions, the use of the insulation trenches 17 between adjacent active cells 15 are advantageous for improving the SOA of the IGBT 1. This is explained in more detail below.

During an on state of the IGBT 1, the P+ type collector layer 3 injects a large amount of excess holes into the N− drift layer 4. Consequently, the carrier concentration in the highly-resistive N− drift layer 4 increases, causing its resistivity to decrease. This temporary increase in conductivity (i.e., a reduction in resistivity) during a conduction period is called conductivity modulation. When the IGBT 1 is switched from an on state to an off state, the excess holes in the N− drift layer 4 either flow into the emitter electrode 21, or are annihilated with excess electrons due to recombination. However, for the prior designs of IGBT which provides a dummy base region between adjacent active cells, the excess holes tend to accumulate within the dummy base region, causing the potential of the dummy base region to rise. The rising potential in the dummy base region may cause dynamic avalanche in the IGBT and thus limit the SOA of the IGBT. By using the insulation trenches 17 (in particular, the isolation structures 10) to replace the dummy base regions, the IGBT 1 of the present disclosure significantly reduces the accumulation of the excess holes within the substrate 2 when the IGBT 1 is switched from an on state to an off state. Accordingly, the IGBT 1 has a reduced risk of dynamic avalanche and an improved SOA.

The use of the insulation trenches 17 between adjacent active cells 15 are also advantageous for improving the switching controllability and reducing switching loss and the EMI noise of the IGBT 1. This is explained in more detail below.

The gate capacitance of an IGBT affects the switching loss and the switching controllability of an IGBT. The gate capacitance includes the gate-emitter capacitance (C_{GE}) and the miller capacitance (C_{GC}).

By providing the insulation trenches 17 between neighbouring ones of the active cells 15, the gate-emitter capacitance (C_{GE}) of the IGBT 1 is significantly reduced by an amount which is equal to the gate-emitter capacitance (C_{GE}) of a trench gate structure (either an active trench gate or a dummy trench gate) which otherwise could be provided at the locations of the isolation structures 10 of the insulation trenches 17.

The Miller capacitance C_{GC} exists due to the internal structure of an IGBT, and can be considered as including two individual capacitances arranged in series. The first capacitance results from the oxide layer (e.g., the gate insulator 11) of the gate and has a constant value. The second capacitance represents the capacitive coupling between the collector and the emitter. As shown in FIG. 1, the isolation structures 10 of the insulation trenches 17 provide a thick dielectric layer between the emitter electrode 21 and the P+ type collector layer 3. Therefore, the insulation trenches 17 significantly reduce the capacitive coupling between the emitter electrode 21 and the collector electrode 19. Accordingly, the use of the insulation trenches 17 is also beneficial for reducing the miller capacitance of the IGBT.

Since the use of the insulation trenches 17 reduce both the gate-emitter capacitance (C_{GE}) and the miller capacitance (C_{GC}), the gate capacitance of the IGBT 1 can be charged and discharged at a faster speed than the prior designs, thereby achieving a reduced switching loss and an improved switching controllability.

Further, in the prior IGBT designs, there are significant parasitic capacitances associated with the dummy base regions and the dummy gate trenches, and the parasitic capacitances cause oscillations and create unpleasant noises during the on/off switching of the IGBT 1. By using the insulation trenches 17 to replace the dummy base regions and the dummy gate trenches, the parasitic capacitances within the device are reduced, and accordingly the EMI noise generated by the IGBT 1 is reduced.

Therefore, as compared to the prior IGBT designs which provide dummy semiconductor regions between neighbouring active cells, the use of the insulation trenches 17 to replace such dummy regions improves the SOA and the switching controllability, and reduces switching loss and the EMI noise of the IGBT 1, while providing a similar level of current density. The length L2 of the insulation trenches 17 along the X axis follows the design rule of 0.5≤L2/L1≤2 to keep uniform electric field distribution on the chip front side (thereby improving the reliability of the IGBT 1) and to maintain process uniformity and controllability.

In addition, the N type first implant zones 13 are useful for improving the conductivity modulation in the IGBT 1 by enhancing the carrier profile in the N− type drift layer 4 in an on state, thereby advantageously reducing V_{CE,sat} of the IGBT 1. Therefore, the IGBT 1 presents an improved trade-off performance amongst the on-state voltage drop V_{CE,sat}, the switching loss E_{SW} and the safe operation area SOA. The IGBT 1 provides an improved efficiency as well as an improved reliability as compared to prior designs of IGBTs.

Further, the first implant zones 13 together with the insulation trenches 17 advantageously enable concurrent improvements in V_{CE,sat} and SOA of the IGBT 1 as compared to prior IGBT designs in which active cells are immediately next to each other. More specifically, by providing the insulation trenches 17 between neighbouring ones of the active cells 15, the IGBT 1 has a reduced channel density relative to a typical IGBT design. The reduced channel density results in an improved SOA (in particular, SCSOA). Normally, the reduced channel density would also cause an increase of V_{CE,sat}. However, with the first implant zone 13, it is possible to maintain V_{CE,sat} at the same level or even to reduce V_{CE,sat} as compared to the prior designs.

The N type buffer layer 6 may also be referred to as a field stop layer, because it terminates the electrical field within the IGBT 1. The buffer layer 6 is useful for reducing the on-state voltage drop V_{CE,sat} of the IGBT 1, and makes the IGBT 1 a punch-through (PT) IGBT. It would be appreciated that the N type buffer layer 6 may be omitted. It would further be appreciated that the first implant zones 13 may also be omitted.

It would further be appreciated that rather than having two gate electrodes 9, each insulation trench 17 may comprise a single gate electrode 9 at one side thereof. In this way, each active cell would provide a single current channel during an on state of the IGBT 1. The single current channel would be located at a side of the active cell which opposes a gate electrode 9 across a gate insulator 11 of a neighbouring insulation trench 17. The emitter region 7 formed at the other side of the active cell which is not adjacent to any gate electrode may be omitted. The IGBT modified in this way provides a lower current density, which is approximately a half of the current density achievable by the IGBT 1, and is useful for applications requiring a lower current density.

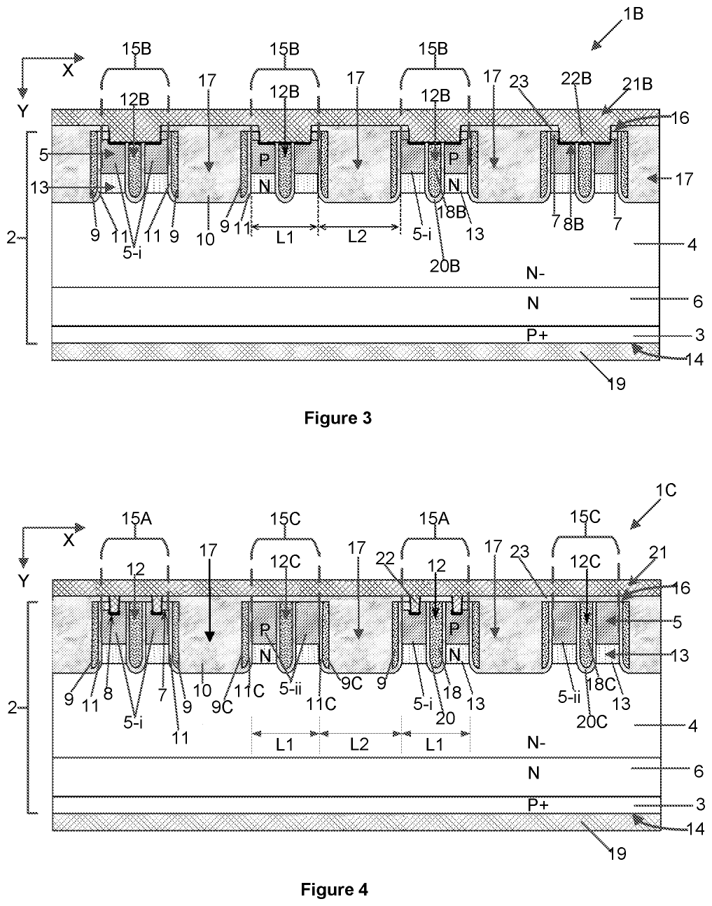

FIG. 2 schematically illustrates a cross-sectional view of a trench-gate IGBT 1A according to a second embodiment of the present disclosure. Elements of the IGBT 1A that are identical to those of the IGBT 1 are identified using the same labels. Elements of the IGBT 1A that correspond to, but are different from those of the IGBT 1 are labelled using the same numerals but with a letter ‘A’ for differentiation. The features and advantages described above with reference to the first embodiment are generally applicable to the second embodiment.

The IGBT 1A includes a plurality of active cells 15A and a plurality of insulation trenches 17. As compared to the active cells 15 shown in FIG. 1, each of the active cells 15A further includes a dummy gate trench 12. The dummy gate trench 12 is located in the middle of the respective active cell 15A (or the mesa region). The dummy gate trench 12 comprises a gate insulator 20 and a dummy gate electrode 18. The expressions “dummy gate electrode” and “dummy gate trench” mean that the respective gate electrode within the corresponding gate trench is not a control electrode, and cannot be used to control the on/off switching of any current channel of the IGBT 1A. The gate insulator 20 and the dummy gate electrode 18 may be made of the same material as the gate insulator 11 and the (active) gate electrode 9, respectively. In particular, the gate insulator may be, for example, a thin layer of oxide film, and the dummy gate electrode 18 may be made of polysilicon.

As compared to the active cell 15 shown in FIG. 1, the dummy gate trench 12 has replaced a portion of the active base region 5-i between the two emitter regions 7, and separated the active base region 5-i of FIG. 1 into two smaller active base regions 5-i. In this way, the active mesa region in the IGBT 1A is more than halved, which enhances the electron injection from the emitter side to reduce V_{CE,sat}. The dummy gate trench 12 also improves the electric field distribution within the mesa region, thereby providing an improved SOA.

Each of the active cells 15A provides two current channels (or conducting paths) at opposite sides of the respective active cell during an on state of the IGBT 1A. This is similar to the active cells 15 as described above. Further, the two current channels are provided at opposite sides of the dummy gate trench 12 within the respective active cell.

While FIG. 2 shows that each active cell 15A includes a single dummy gate trench 12, it would be understood that more than one dummy gate trench 12 may be provided within each active cell 15A. In that case, the two current channels of each active cell 15A are provided at opposite sides of the more than one dummy gate trench 12 viewed as a group.

While it is not shown in FIG. 2, all of the dummy gate electrodes 18 may be electrically connected to the emitter electrode 21 which is normally grounded. The connection point between the dummy gate electrodes 18 and the emitter electrode 21 may be at both ends of the array of the active cells 15A.

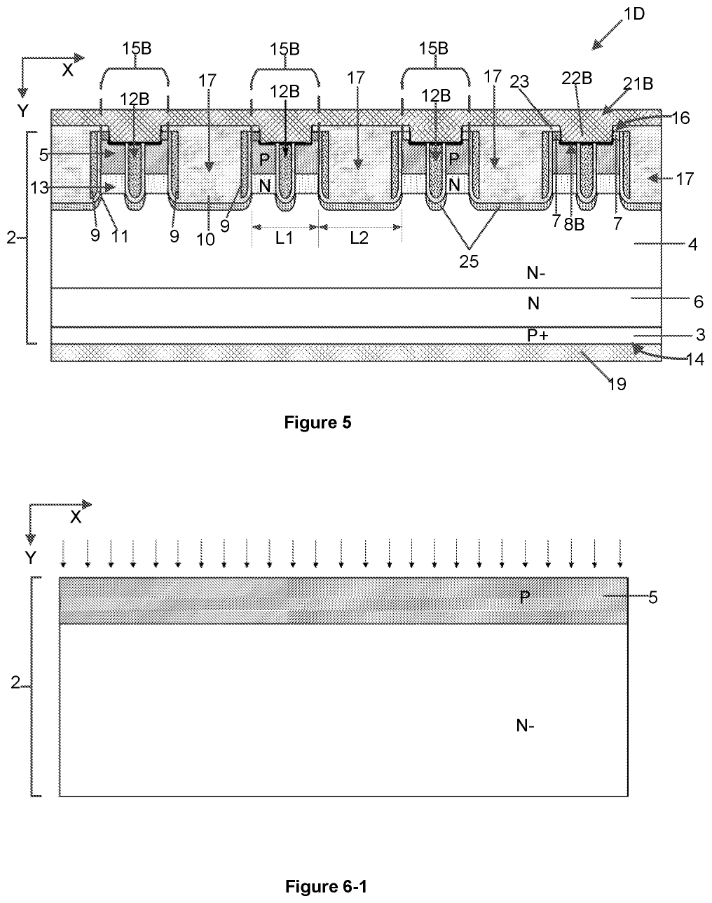

In the example provided by FIG. 2, each gate electrode 9 is shown as approximately a half of each dummy gate electrode 18. It would be appreciated that the illustration is merely provided for conceptual clarity and the relative sizes of the gate electrodes 9 and 18 may vary. FIG. 3 schematically illustrates a cross-sectional view of a trench-gate IGBT 1B according to a third embodiment of the present disclosure. Elements of the IGBT 1B that are identical to those of the IGBT 1 or the IGBT 1A are identified using the same labels. Elements of the IGBT 1B that correspond to, but are different from those of the IGBT 1 or the IGBT 1A are labelled using the same numerals but with a letter ‘B’ for differentiation. The features and advantages described above with reference to the first embodiment are generally applicable to the third embodiment.

The IGBT 1B is similar to the IGBT 1A. In the IGBT 1A, the emitter electrode 21 includes two emitter contact vias 22 to form electrical connections with the two emitter regions 7 of an active cell 15A, respectively. However, in the IGBT 1B, the emitter electrode 21B includes a single, wide, emitter contact trench 22B to form electrical connections with the two emitter regions 7 of an active cell 15B simultaneously. Further, the single emitter contact trench 22B is also electrically connected with the dummy gate electrode 18B of the same active cell 15B.

In this way, the dummy gate electrodes 18B are electrically connected to the emitter electrode 21B which is normally grounded.

An emitter contact trench 22B has a length which is greater than that of the dummy gate trench 12B along the X axis. In order to manufacture the emitter contact trenches 22B, the P type active base regions 5-i and the dummy gate trench 12B between the two emitter regions 7 of the same active cell 15B were etched along the Y axis, and emitter metal was deposited to fill the emitter contact trenches 22B. Therefore, the dummy gate trench 12B is shorter than the active gate electrodes 9 or the dummy gate trench 12 (shown in FIG. 2) along the Y axis. A combination of the emitter contact trench 22B and the dummy gate trench 12B may also be referred to as a recessed emitter trench (RET) gate. Accordingly, the IGBT 1B may be referred to as a RET-IGBT.

A heavily doped P+ type region 8B is further provided at the interface between an emitter contact trench 22B, on the one hand, and the corresponding P type active base regions 5-i and the dummy gate electrode 18B, on the other hand. Similar to the P+ type region 8 used in the IGBT 1 or 1A, the P+ type region 8B is useful for reducing the contact resistance between metal and semiconductor.

The use of the wide emitter contact trench 22B provides several advantages.

Firstly, it electrically connects both of the emitter regions 7 and the dummy gate electrode 18B within an active cell 15B to the emitter electrode 21B. In this way, there is no need to provide separate electrical connections in order to ground the dummy gate electrode 18B.

Secondly, as compared to the IGBT 1A, the use of the wide emitter contact trench 22B reduces the minimum distance between each of the active gate electrode and the dummy gate trench. In the IGBT 1A, the emitter contact via 22 is arranged between the active gate electrode 9 and the dummy gate trench 12. The minimum distance between each of the active gate electrode 9 and the dummy gate trench 12 along the X axis is a sum of (i) a length of one emitter region 7, (ii) a minimum length of the via 22, and (iii) a minimum spacing between the via 22 and the dummy gate trench 12. However, in the IGBT 1B, because the wide emitter contact trench 22B continuously extends between the two emitter regions 7 and is also in contact with the dummy gate trench 12B, the minimum distance between each of the active gate electrode 9 and the dummy gate trench 12B is no longer restricted by (ii) and (iii). In this way, the distance between the active gate electrode 9 and the dummy gate trench 12B may be significantly reduced, thereby improving the current density and the V_{CE,sat} of the IGBT 1B. Further, in order to form the emitter contact vias 22, a lithography process which is capable of delivering fine geometry trench technology may be required. In contrast, the wide emitter contact trench 22B relaxes such requirements imposed on the lithography process.

Thirdly, each emitter contact trench 22B may provide a wide contact area between the emitter electrode 21B and the respective P type active base regions 5-i. The wide contact area is efficient in collecting holes and making holes flow away from the PN junction between the N+ type emitter regions 7 and the P type active base regions 5-i. This allows the IGBT 1B to provide excellent SOA performance (in particular Reverse Bias (RB) SOA and SCSOA).

While FIG. 3 shows that each active cell 15B includes a single dummy gate trench 12B, it would be understood that there may be more than one dummy gate trench 12B within each active cell 15B. In that case, each emitter contact trench 22B would be electrically connected to all of the dummy gate trenches within the same active cell.

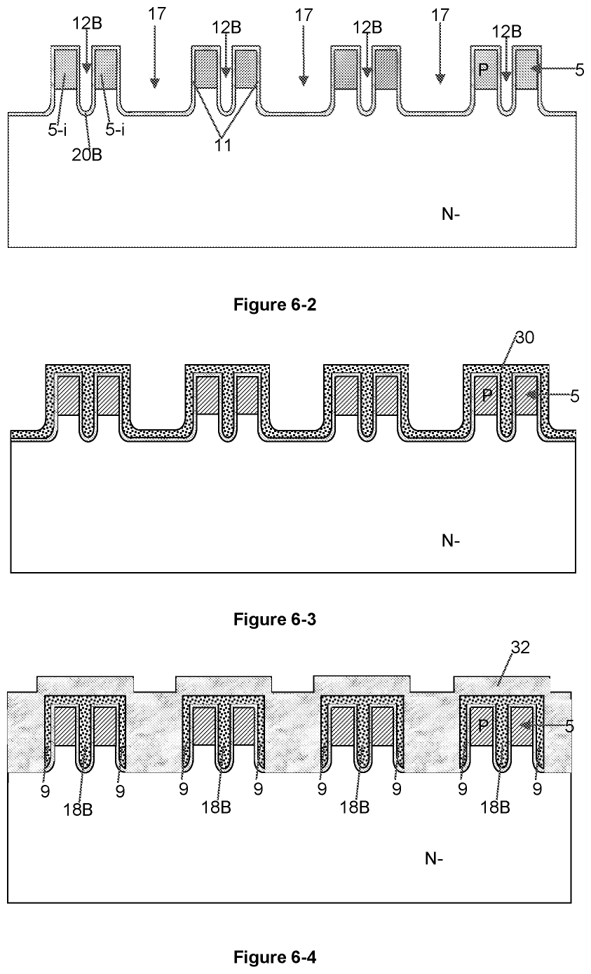

FIG. 4 schematically illustrates a cross-sectional view of a trench-gate IGBT 1C according to a fourth embodiment of the present disclosure. Elements of the IGBT 1C that are identical to those of the IGBTs 1, 1A, 1B are identified using the same labels. Elements of the IGBT 1C that correspond to, but are different from those of the IGBTs 1, 1A, 1B are labelled using the same numerals but with a letter ‘C’ for differentiation. The features and advantages described above with reference to the first embodiment are generally applicable to the fourth embodiment.

The IGBT 1C is similar to the IGBT 1A of FIG. 2, but further includes a plurality of dummy cells 15C within the semiconductor substrate 2. As illustrated in FIG. 4, a single dummy cell 15C is provided between two adjacent active cells 15A along the X axis. The dummy cells 15C are semiconductor regions formed in the substrate 2. A single insulation trench 17 is used to isolate any dummy cell 15C from its neighbouring active cells 15A. In this way, a combination of two insulation trenches 17 and a dummy cell 15C are provided immediately between two adjacent active cells 15A along the X axis.

It would be appreciated that more than one dummy cell 15C may be provided between two adjacent active cells 15A. In that case, an insulation trench 17 would be provided between each dummy cell 15C and its neighbouring dummy or active cell so as to isolate the cells (whether active or dummy) from one another. In other words, a combination of M (M being an integer ≥2) dummy cell 15C and M+1 insulation trenches 17 may be provided immediately between two adjacent active cells 15A along the X axis.

As described above, the expression “active cell” means that the respective cell would provide at least one conducting channel during an on-state of the IGBT. Conversely, the expression “dummy cell” means that the respective cell would not be able to provide any conducting current channel during the on state of the IGBT. Each dummy cell 15C comprises a dummy gate trench 12C comprising a gate insulator 20C and a dummy gate electrode 18C. The dummy gate trench 12C has the same dimension and configuration as the dummy gate trench 12 provided in an active cell 15A.

Each dummy cell 15C further comprises a P type dummy base region 5-ii and a first implant zone 13 at either side of its dummy gate trench 12. A first implant zone 13 is provided between a P type dummy base region 5-ii and the N− drift layer 4. All of the first implant zones 13 within the active and dummy cells may be formed in the substrate 2 simultaneously by one implantation step. Similar to the active base regions 5-i of the active cells 15A, the dummy base regions 5-ii are parts of the P type base layer 5. The dummy base regions 5-ii are designed to have the same dimension and the same doping concentration as the active base regions 5-i. The dummy base regions 5-ii may also be referred to as dummy wells.

There is no emitter region within any of the dummy base regions 5-ii. Therefore, there is no current channel flowing through any of the dummy cells 15C during the on state of the IGBT 1C. The gate electrode of an insulation trench 17 neighbouring a dummy cell 15C is called a dummy gate electrode 9C. However, the dummy gate electrode 9C has the same dimension as the active gate electrode 9. Further, the dummy gate electrodes 9C may be electrically connected to the active gate electrodes 9. In this way, the dummy gate electrode 9C itself may not be distinguishable from the active gate electrode 9. Alternatively, the dummy gate electrode 9C may be electrically connected to the emitter electrodes 21B which is normally grounded.

As shown in FIG. 3, each dummy cell 15C has a length L1 along the X axis which is identical to the length L1 of an active cell 15A. The lengths L1 and L2 in the IGBT 1B still satisfy the design rule of 0.5≤L2/L1≤2. More preferably, the lengths L1 and L2 satisfy the design rule of L2/L1≤1.7, or most preferably L2/L1≤1.5, and/or L2/L1≥1. Since the dummy cells 15C and the active cells 15A are both semiconductor regions formed in the substrate 2 and are designed to have very similar structures and configurations, the particular design rules between L1 and L2 remains useful for keeping uniform electric field distribution on the chip front side, and for maintaining process uniformity and controllability.

It would be understood that with the same lengths L1 and L2, the IGBT 1C has a lower channel density than the IGBT 1 due to the fact that the dummy cells 15C do not provide any conducting channel during the on state of the IGBT 1C. Accordingly, the IGBT 1C generally provides a lower current density, which is approximately a half of the current density achievable by the IGBT 1A. Therefore, the IGBT 1C is useful for applications requiring a lower current density.

As described above, the IGBTs 1 and 1A use the insulation trenches 17 to replace the entirety of the dummy semiconductor regions used in prior designs. Turning to FIG. 4, it is clear that the IGBT 1C uses its insulation trenches 17 to replace a substantial part (e.g., more than two thirds in the example provided by FIG. 4) of the dummy semiconductor regions used in prior designs. As a result, the IGBT 1C still has a reduced amount of excess holes accumulated within the substrate 2 (in particular in the dummy base regions 5-ii) when the IGBT 1C is switched from an on state to an off state. Accordingly, the IGBT 1C has a reduced risk of dynamic avalanche and an improved SOA. Further, by using the insulation trenches 17 to replace a substantial part of the dummy semiconductor regions used in prior designs, the IGBT 1C has a reduced gate-emitter capacitance (C_{GE}) and a reduced Miller capacitance C_{GC} as compared to prior designs for similar reasons as described above for the first embodiment. Consequently, the insulation trenches 17 are also advantageous for improving the switching controllability and reducing switching loss and the EMI noise of the IGBT 1C.

The dummy base regions 5-ii may be electrically connected to the emitter electrode 21 which is normally grounded. Further, the dummy gate electrode 18 may also be connected to the emitter electrode 21. The dummy gate electrode 18C may also be connected to the emitter electrode 21 or may be kept floating.

It would be appreciated that the dummy gate trenches 12 and 12C may be omitted from FIG. 4. Further, the emitter contact vias 22 and the dummy gate trench 12 for each active cell 15A may be replaced with the wide emitter contact trench 22B and the etched dummy gate trench 12B as shown in FIG. 3. Further still, the first implant zones 13 may be omitted from the dummy cells 15C.

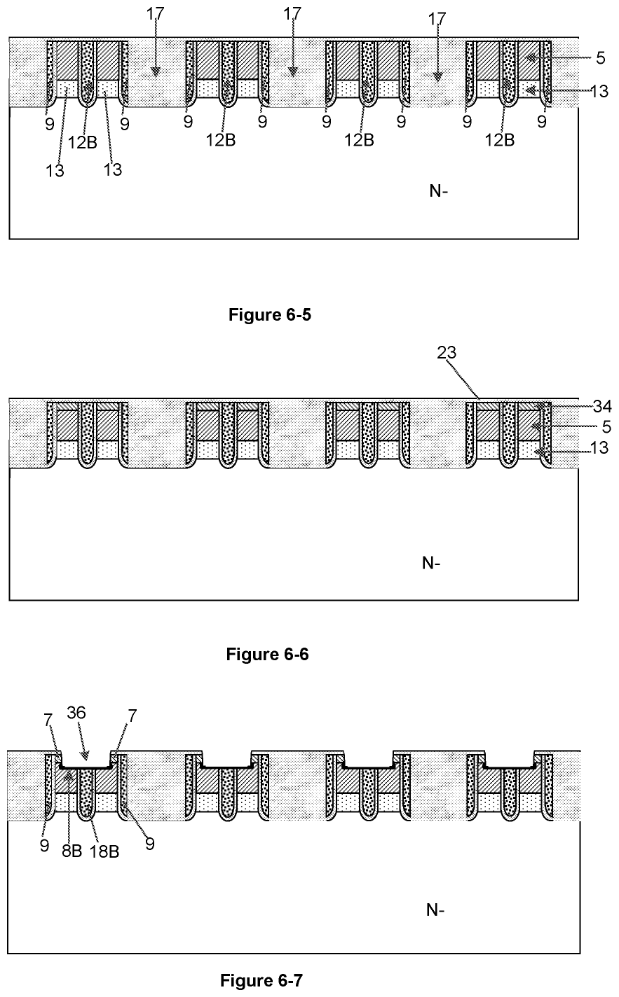

FIG. 5 schematically illustrates a cross-sectional view of a trench-gate IGBT 1D according to a fifth embodiment of the present disclosure. Elements of the IGBT 1D that are identical to those of the IGBTs described above are identified using the same labels. Elements of the IGBT 1D that correspond to, but are different from those of the IGBTs described above are labelled using the same numerals but with a letter ‘D’ for differentiation. The features and advantages described above with reference to the first embodiment are generally applicable to the fifth embodiment.

As compared to the IGBT 1B, the IGBT 1D has additional second implant zones 25. The second implant zones 25 are P type, and are formed by implantation. Therefore, all of the second implant zones 25 may be formed in the substrate 2 simultaneously.

As shown in FIG. 5, some of the second implant zones 25 are provided under the insulation trenches 17, i.e., between the insulation trenches 17 and the N− drift layer 4.

The second implant zones 25 are useful in that they shield the gate insulator 11 and the active gate electrode 9 from the bombing holes injected by the P+ collector layer 3 during an on state of the IGBT 1D. Accordingly, the gate insulator 11 and the active gate electrode 9 are protected by the second implant zones 25 from trapping holes bombing from the collector layer 3. As a result, the second implant zones 25 under the insulation trenches 17 (in particular, under the gate electrode 9 and the gate insulator 11) improve the reliability of the IGBT 1D.

Further, being P type, the second implant zones 25 under the insulation trenches 17 are also useful for depleting the N− drift layer 4 in the blocking state, thereby supporting a high breakdown voltage for the IGBT 1D.

As further shown in FIG. 5, the second implant zones 25 are also provided under the dummy gate trenches 12B, i.e., between the dummy gate trenches 12B and the N− drift layer 4. Similarly, such second implant zones 25 under the gate trenches 9, 9B provide better blocking capability.

The second implant zones 25 may be electrically connected to the emitter electrode 21 (which is normally grounded) or may be floating (i.e., not electrically connected to any electrodes of the IGBT 1D).

It would be appreciated that the second implant zones 25 may be provided within each of the IGBTs 1A, 1B and 1C described above. It would also be appreciated that the second implant zones 25 under the dummy gate trenches may be omitted, such that the second implant zones 25 are only formed under the insulation trenches 17.

The IGBTs described above are all N-channel IGBTs. It would be appreciated that the doping types of each region/layer may be changed to the opposite doping types so as to provide P-channel IGBTs.

FIGS. 6-1 to 6-8 illustrate a method for manufacturing the IGBT 1B of the third embodiment.

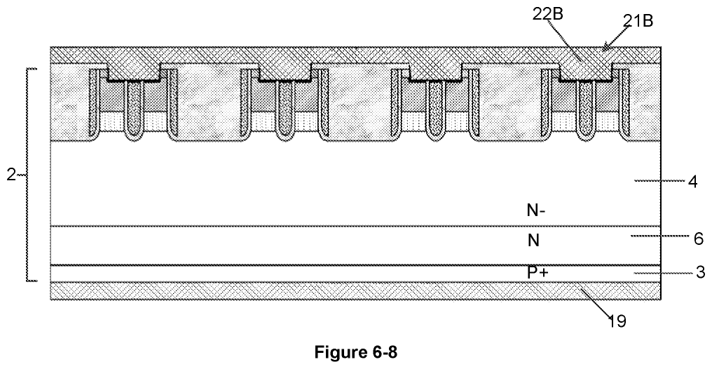

At the first step as illustrated by FIG. 6-1, P type dopants (such as, Boron) are implanted into a semiconductor substrate 2 to form a P type base layer 5 at a top side of the substrate. The semiconductor substrate 2 is a lightly doped N− type substrate, which has a doping concentration corresponding to the doping concentration of the N− drift layer 4. The semiconductor substrate 2 is made of a single-crystalline semiconductor material, which may be, for example, silicon (Si), silicon carbide (SiC), germanium (Ge), or a silicon germanium crystal (SiGe). Dimensions and doping concentrations given in the following refer to silicon IGBTs, by way of example.

At the second step as illustrated by FIG. 6-2, the top side of the substrate 2 is selectively etched to form trenches in the substrate 2. The trenches provide the dummy gate trenches 12B and the insulation trenches 17 in the finished product. Anisotropic dry etching may be used at this step in order to form vertical sidewalls of the trenches. The etching depth may be between 3 micrometres (μm) to 7 μm. A gate oxide layer (e.g., silicon dioxide) is then thermally grown on the surfaces of the substrate 2. The gate oxide layer provides the gate insulators 11 and 20B. The thickness of the gate oxide layer may be between 900 Å to 1300 Å. Before the gate oxide layer is grown, steps of growing and removing a sacrificial gate oxide layer may be optionally performed. The thickness of the sacrificial gate oxide layer may be between 1000 Å to 3000 Å. It would be understood that during the thermal growth of the gate oxide layer and/or the sacrificial gate oxide layer, the dopants implanted at the first step would move to a deeper depth of the substrate 2 to form the active base regions 5-i.

After the gate oxide layer is formed, another implantation step (not shown in FIG. 6-2) may be performed to provide the second implant zones 25 required by the IGBT 1D according to the fifth embodiment. In particular, P type dopants (e.g., Boron) may be selectively implanted with a dose of 1×10¹² to 1×10¹⁴ ions/cm², an ion energy of 50˜400 keV and a tile angle of 0 degree, so as to form the P type implant zone 25 under the dummy gate trenches 12B and the insulation trenches 17.

At the third step as illustrated by FIG. 6-3, a layer of polysilicon 30 is deposited on the top surface of the substrate 2 to fill the dummy gate trenches 12B.

At the fourth step as illustrated by FIG. 6-4, the deposited polysilicon which is at the bottom of the insulation trenches 17 are etched off. In this way, the remaining polysilicon forms the active gate electrodes 9 and the dummy gate electrodes 18B.

Further, a thick layer of dielectric material 32 (e.g. silicon dioxide) is deposited on the top surface of the substrate 2 to fill the insulation trenches 17.

At the fifth step as illustrated by FIG. 6-5, a chemical mechanical polishing (CMP) process is employed to smooth the top surface of the substrate 2, followed by wet cleaning of the substrate 2. Subsequently, another layer of dielectric material (e.g., silicon dioxide) is deposited on the top surface of the substrate 2. The thickness of that layer may be between 200 Å˜800 Å.

Further, N type dopants (e.g., Phosphorous) are selectively implanted into the substrate 2 with a high ion energy (e.g., >2.0 MeV) to form the first implant zones 13 within the active cells 15B. Thermal annealing follows to activate the implanted N type dopants. High ion energy is required because of the depth of the first implant zones 13 within the substrate 2.

At the sixth step as illustrated by FIG. 6-6, N type dopants (e.g., Arsenic or Phosphorous) are selectively implanted into the base layer 5 to form an N+ type emitter layer 34. The dielectric layer (e.g., silicon dioxide) previously deposited on the top surface of the substrate 2 is then cleaned. A further layer of dielectric material (e.g., silicon dioxide) with an exemplary thickness of greater than 0.6 μm is then deposited on the top surface of the substrate to form the interlay dielectric 23.

At the seventh step as illustrated by FIG. 6-7, the interlay dielectric 23, the emitter layer 34, the base layer 5 and the dummy gate trenches 12B are selectively etched along the Y axis, for example, by an etching depth of 0.3-0.5 μm. The etching forms trenches 36. The dimension and location of the trenches 36 correspond to those of the emitter contact trenches 22B in the finished product. The etching further separates the N+ type emitter layer 34 into two emitter regions 7 within each active cell 15B. P type dopants (e.g., Boron) are then implanted and thermally annealed to form the P+ type contact regions 8B.

At the eighth step as illustrated by FIG. 6-8, metal is deposited on the top surface of the substrate 2 to fill the emitter contact trenches 22B and to form the emitter electrode 21B. The bottom side of the substrate 2 may be grinded to a target wafer thickness as required, and is then doped to form the N type buffer layer 6 and the P+ type collector layer 3. Metal is further deposited on the bottom surface of the substrate 2 to form the collector electrode 19. The process carried out to the bottom side of the substrate 2 may be performed during or after the above described processing steps carried out to the top side.

While the above paragraphs only describe the methods for manufacturing the IGBTs 1B and 1D, it would be understood that the described methods may be easily adapted (by for example modifying the masks used during the implantation and etching steps) in order to manufacture the IGBTs of other embodiments.

While the embodiments described above refer to IGBTs only, it would be appreciated that the present disclosure may be applied to other types of power semiconductor devices.

The skilled person will understand that in the preceding description and appended claims, positional terms such as ‘top’, ‘bottom’, ‘under’, ‘lateral’, ‘vertical’, etc. are made with reference to conceptual illustrations of a power semiconductor device, such as those showing standard cross sectional views and those shown in the appended drawings. These terms are used for ease of reference but are not intended to be of limiting nature. These terms are therefore to be understood as referring to a semiconductor structure when in an orientation as shown in the accompanying drawings.

Although the disclosure has been described in terms of preferred embodiments as set forth above, it should be understood that these embodiments are illustrative only and that the claims are not limited to those embodiments. Those skilled in the art will be able to make modifications and alternatives in view of the disclosure which are contemplated as falling within the scope of the appended claims. Each feature disclosed or illustrated in the present specification may be incorporated in the disclosure, whether alone or in any appropriate combination with any other feature disclosed or illustrated herein.

1. A power semiconductor device, comprising:
a semiconductor substrate comprising:
a base layer selectively provided at a first side of the semiconductor substrate, and wherein the base layer has a first conductivity type;
a collector layer provided at a second side of the semiconductor substrate, wherein the second side is opposite to the first side, and wherein the collector layer has the first conductivity type; and
a drift layer having a second conductivity type opposite to the first conductivity type, wherein the drift layer is arranged between the collector layer and the base layer;
an active cell provided in the semiconductor substrate, wherein the active cell comprises an emitter region which has the second conductivity type and an active base region which is a part of the base layer; and
an insulation trench provided in the semiconductor substrate and neighbouring the active cell, wherein: the insulation trench extends from a surface of the semiconductor substrate at the first side into the drift layer along a first direction; the insulation trench comprises a gate electrode and a dielectric material disposed therein; and the gate electrode is configured to control an on/off status of a current channel within the active cell;
wherein the active cell has a first length L1 along a second direction perpendicular to the first direction, and the insulation trench has a second length L2 along the second direction, and the first and second lengths L1 and L2 satisfy the relationship of 0.5≤L2/L1≤2.

2. A power semiconductor device according to claim 1, wherein the first and second lengths L1 and L2 further satisfy the relationship of L2/L1≤1.7.

3. A power semiconductor device according to claim 1, wherein the active cell further comprises a first implant zone provided between the active base region and the drift layer, wherein the first implant zone is of the second conductivity type and has a higher doping concentration than the drift layer.

4. A power semiconductor device according to claim 1, the power semiconductor device comprising a further insulation trench neighbouring the active cell,
wherein the further insulation trench extends from the surface of the semiconductor substrate into the drift layer along the first direction and comprises a gate electrode and a dielectric material disposed therein; and
wherein the gate electrode of the further insulation trench is configured to control an on/off status of a further current channel within the active cell.

5. A power semiconductor device according to claim 4, wherein the current channel and the further current channel are arranged at opposite sides of the active cell.

6. A power semiconductor device according to claim 1, wherein the gate electrode is a first gate electrode, and the insulation trench comprises a second gate electrode, and wherein the first and second gate electrodes are arranged at opposite sides of the insulation trench.

7. A power semiconductor device according to claim 1, wherein the active cell further comprises a dummy gate trench, the dummy gate trench comprising a dummy gate insulator and a dummy gate electrode disposed therein.

8. A power semiconductor device according to claim 7, wherein the dummy gate trench is arranged in the middle of the active cell along the second direction.

9. A power semiconductor device according to claim 7, further comprising an emitter electrode, wherein the emitter electrode comprises an emitter contact trench extending along the first direction into the base layer, wherein the emitter contact trench is electrically connected to the emitter region and the dummy gate electrode.

10. A power semiconductor device according to claim 9, wherein the emitter contact trench has a greater length than the dummy gate trench along the second direction.

11. (canceled)

12. A power semiconductor device according to claim 1, further comprising a second implant zone between the insulation trench and the drift layer, the second implant zone having the first conductivity type.

13. A power semiconductor device according to claim 12, wherein the active cell further comprises a dummy gate trench, the dummy gate trench comprising a dummy gate insulator and a dummy gate electrode disposed therein, and the second implant zone is also provided within the active cell between the dummy gate trench and the drift layer.

14. (canceled)

15. A power semiconductor device according to claim 1, further comprising a dummy cell, wherein the dummy cell comprises a dummy base region which is a part of the base layer.

16. (canceled)

17. (canceled)

18. A power semiconductor device according to claim 15, wherein the active cell further comprises a first implant zone provided between the active base region and the drift layer, wherein the first implant zone is of the second conductivity type and has a higher doping concentration than the drift layer, and the first implant zone is also provided within the dummy cell between the dummy base region and the drift layer.

19. (canceled)

20. A power semiconductor device according to claim 1, wherein the power semiconductor device comprises a plurality of the active cells and a plurality of the insulation trenches, and each active cell is provided immediately between two of the insulation trenches along the second direction.

21. A power semiconductor device according to claim 20, wherein the power semiconductor device further comprises a plurality of dummy cells each comprising a dummy base region which is a part of the base layer, and wherein at least one of the dummy cells and at least two of the insulation trenches are provided between neighbouring ones of the active cells along the second direction.

22. A power semiconductor device according to claim 21, wherein the insulation trenches are provided between a dummy cell and an active cell, or between two dummy cells, along the second direction.

23. (canceled)

24. A power semiconductor device according to claim 1, wherein the power semiconductor device comprises an insulated-gate bipolar transistor.

25. A method of manufacturing a power semiconductor device, the method comprising:
providing a semiconductor substrate comprising:
a base layer provided at a first side of the semiconductor substrate, wherein the base layer has a first conductivity type; and
a drift layer having a second conductivity type opposite to the first conductivity type;
selectively etching the base layer and the drift layer to form an insulation trench within the semiconductor substrate;
forming a gate electrode within the insulation trench and filling the insulation trench with a dielectric material;
selectively forming an emitter region having the second conductivity type within the base layer at the first side of the semiconductor substrate, wherein the emitter region and a part of the base layer in which the emitter region is arranged provide an active cell, and wherein the insulation trench neighbours the active cell, and the gate electrode is configured to control an on/off status of a current channel within the active cell; and
forming a collector layer at a second side of the semiconductor substrate, the collector layer having the first conductivity type, wherein the second side is opposite to the first side, and the drift layer is arranged between the collector layer and the base layer;
wherein:
the insulation trench is configured to extend from a surface of the semiconductor substrate at the first side into the drift layer along a first direction;
the active cell has a first length L1 along a second direction perpendicular to the first direction, and the insulation trench has a second length L2 along the second direction; and
the first and second lengths L1 and L2 satisfy the relationship of 0.5≤L2/L1≤2.
